(19) United States
(12) Patent Application Publication
(10) Pub. No.: US 2009/0127655 A1
(43) Pub. Date: May 21, 2009

(54) CAPACITOR FOR SEMICONDUCTOR DEVICE AND METHOD FOR FABRICATING THE SAME

(76) Inventor: Seung-Min Lee, Namyangiu-si (KR)

Correspondence Address: SHERR & VAUGHN, PLLC, 620 HERNDON PARKWAY, SUITE 200, HERNDON, VA, 20170, US

(21) Appl. No.: 12/267,566

(22) Filed: Nov. 8, 2008

(30) Foreign Application Priority Data
Nov. 16, 2007 (KR) 10-2007-0117292

(51) Int. Cl. H01L 29/92; H01L 21/02

(52) U.S. Cl. 257/532; 438/393; 257/E29.343; 257/E21.008

(57) ABSTRACT

A capacitor for the semiconductor device may include a bottom electrode formed over a semiconductor substrate, a dielectric film pattern formed over the bottom electrode, an insulating member formed over a peripheral portion of the top surface of the dielectric film pattern, and a top electrode formed over the insulating member and dielectric film pattern. Capacitor properties are improved and capacitor values are maintained as constant by reducing a parasitic capacitance generated from edges of a capacitor electrode. Therefore, embodiments make it possible to improve semiconductor device properties and yields.

The present application claims priority under 35 U.S.C. 119 to Korean Patent Application No. 10-2007-0117292 (filed on Nov. 16, 2007), which is hereby incorporated by reference in its entirety.

### BACKGROUND

With recent increases in semiconductor device integration density, semiconductor devices with analog capacitors integrated within a logic circuit have been studied and developed for use in products. A Polysilicon/Insulator/Polysilicon (PIP) capacitor and a Metal/Insulator/Metal (MIM) capacitor may be used as analog capacitors in logic circuits. Such a PIP capacitor or a MIM capacitor is independent from bias in a way that is different from a Metal Oxide Silicon (MOS) capacitor or a junction capacitor. The PIP capacitor or the MIM capacitor is largely used in analog products requiring accuracy in the capacitance value.

A bottom electrode and a top electrode of the MIM capacitor may be fabricated during the process of forming a metal wire. In a MIM capacitor, there is a parasitic capacitance generated in the electrode edge in addition to the capacitance between the top electrode and the bottom electrode. The parasitic capacitance creates difficulties in obtaining a desired capacitance value of a MIM capacitor. The parasitic capacitance changes the actual capacitance value from a design value in the MIM capacitor.

### SUMMARY

Embodiments relate to a capacitor for a semiconductor device and a method for fabricating the same. Embodiments relate to a capacitor for a semiconductor device having good properties and a method for fabricating the same.

Embodiments relate to a capacitor for a semiconductor device which may include a bottom electrode formed over a semiconductor substrate, a dielectric film pattern formed over the bottom electrode, an insulating member formed over a peripheral portion of the top surface of the dielectric film pattern, and a top electrode formed over the insulating member and dielectric film pattern.

Embodiments relate to a method for fabricating a capacitor for a semiconductor device which may include: providing a semiconductor substrate; forming a bottom electrode over a semiconductor substrate; forming a dielectric film over the bottom electrode; forming an insulating film over the dielectric film; wet etching a portion of the insulating film to expose a portion of the dielectric film over the top portion of the bottom electrode; forming a top electrode film over the exposed dielectric film and the insulating film; and patterning the top electrode film, the insulating film and the dielectric film to form a top electrode, an insulating member disposed below the edge of the top electrode and a dielectric film pattern, respectively.

### DRAWINGS

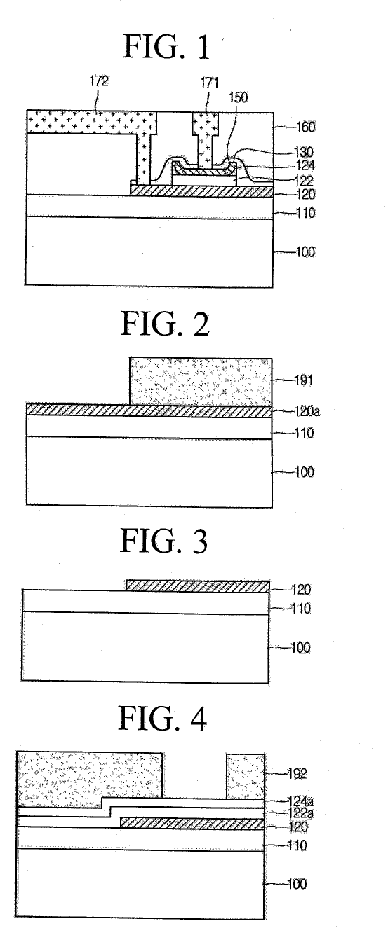

Example FIG. 1 is a cross-sectional view showing a capacitor for a semiconductor device according to embodiments.

Example FIGS. 2 to 11 are cross-sectional views showing processes of fabricating a capacitor for a semiconductor device according to embodiments.

### DESCRIPTION

Example FIG. 1 is a cross-sectional view showing a capacitor for a semiconductor device according to embodiments. As shown in example FIG. 1, the capacitor for the semiconductor device according to embodiments may include a bottom electrode 120, and a top electrode 130 formed over the top of the bottom electrode 120. A dielectric film pattern 122 may be formed between the top electrode 130 and bottom electrode 120. An insulating member 124 may be formed along edges between the dielectric film pattern 122 and top electrode 130.

A pad nitride film 110 may be formed over a substrate 100, which may have additional structures formed below the pad nitride film 110. A bottom electrode 120 may be formed over a portion of the pad nitride film 110. The bottom electrode 120 may be made of at least one selected from the group consisting of Ti, TiN, Ta, TaN, Cu, Al, Pt, Ru, Ir, Rh and Os, and alloys thereof. The bottom electrode 120 may be formed as a single-layer structure or as a multiple-layer structure. A dielectric film pattern 122 may be formed over a portion of the bottom electrode 120. The dielectric film pattern 122 may be made of, for example, a high dielectric constant (high-K) insulating material.

An insulating member 124 may be formed over portion of the dielectric film pattern 122. The insulating member 124 may be formed along edges of the dielectric film pattern 122. The insulating member 124 may be connected along the edges to form a ring shape over the dielectric film pattern 122. The top surface of the insulating member 124 decreases in height from the edges towards the central portion of the dielectric film pattern 122. That is, in cross-sectional views of the insulating member 124 and dielectric film pattern 122, the top surface of the insulating member 124 is rounded in a “U” shape.

A top electrode 130 may be formed over the insulating member 124 and dielectric film 122. The top electrode 130 contacts the central portion of the dielectric film pattern 122 and the insulating member 124 formed along the edges of the dielectric film pattern 122. The top electrode 130 and bottom electrode 120 may be spaced in the central part of the electrode by the thickness of the dielectric film pattern 122. The top electrode 130 and bottom electrode 120 may be spaced at the edge portion of the electrode by the thickness of the dielectric film pattern 122 and insulating member 124. The top electrode 130 may be flat over the central portion of the dielectric film pattern 122, and rounded upwards close to the edge of the top electrode 130 by insulating member 124. In other words, the edge of the top electrode 130 is more distant from the bottom electrode 120 than the central portion of the top electrode 130, such that a parasitic capacitance between the two electrodes is reduced. The top electrode 130 may be made of at least one selected from the group consisting of Ti, TiN, Ta, TaN, Cu, Al, Pt, Ru, Ir, Rh and Os, and alloys thereof. The insulating member 124 may be made of a low dielectric constant (low-K) dielectric material. The insulating member 124 may be, for example, made of an oxide film.

A capacitor having the structure described above may be formed over the substrate 100, and a first insulating film 150 may be formed to cover the bottom electrode 120 and top electrode 130. A second insulating film 160 may be formed over the substrate 100 over which a first insulating film 150 is formed. The first insulating film 150 may be a capping insulator for protecting the capacitance and may be, for example, a silicon nitride film. The second insulating film 160 is formed flat over a top portion of the first insulating film 150.

A first wire 171 which contacts the top electrode 130, passing through the second insulating film 160, and a second wire 172 which contacts the bottom electrode 120 may be formed through the first insulating film 150 and the second insulating film 160. The first wire 171 and second wire 172 may be made of a copper, for example, and may also be made of aluminum and tungsten.

Hereinafter, a method for fabricating a capacitor for a semiconductor device according to embodiments will be described with reference to the accompanying drawings. Example FIGS. 2 to 11 are cross-sectional views showing processes of fabricating a capacitor for a semiconductor device according to embodiments. As shown in example FIG. 2, a pad nitride film 110 and a bottom electrode film 120a are formed over a substrate 100 which may have additional structures formed below the pad nitride film 110. The pad nitride film 110 may be used as an etch stopping layer when a via hole for interlayer connection is formed and may be used as a film for protecting the capacitance. The bottom electrode film 120a may be made of metal material or poly silicon. A first photoresist pattern 191 is formed over a portion of the bottom electrode film 120a.

As shown in example FIG. 3, the bottom electrode film 120a may be etched using the first photoresist pattern 191 as a mask to form a bottom electrode 120. The first photoresist pattern 191 may then be removed.

Thereafter, as shown in example FIG. 4, a dielectric film 122a and a third insulating film 124a may be formed sequentially over the substrate 100 over which the bottom electrode 120 is formed. The dielectric film 122a may be made of a high dielectric constant (high-K) material. The third insulating film 124a may be an oxide film. The third insulating film 124a may be an insulating film having a low dielectric constant (low-K). A second photoresist pattern 192 may be formed over the third insulating film 124a. The second photoresist pattern 192 exposes a portion of the third insulating film 124a over a top portion of the bottom electrode 120.

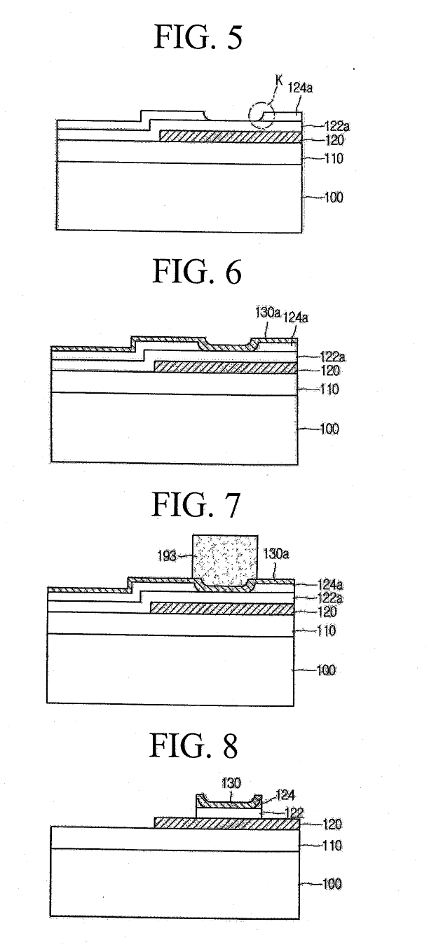

As shown in example FIG. 5, a portion of the dielectric film 122a may be exposed by performing a wet etching on the third insulating film 124a using the second photoresist pattern 192 as a mask. The wet etching process may be an isotropic etching process. A top region of the third insulating film 124a may be more intensely exposed to have a higher etch rate in the top region than that in the bottom region. The etched cross-section of the third insulating film 124a may be rounded in the area designated by ‘K’ in example FIG. 5. The second photoresist pattern 192 may then be removed.

As shown in example FIG. 6, a top electrode film 130a may be formed over the third insulating film 124a and the exposed portion of the dielectric film 122a. The top electrode film 130a may be made of metal material or poly silicon. The top electrode film 130a contacts the exposed dielectric film 122a.

As shown in example FIG. 7, a third photoresist pattern 193 may be formed over the top electrode film 130a. The third photoresist pattern 193 may be formed to cover the exposed dielectric film 122a and the etched sides of third insulating film 124a.

As shown in example FIG. 8, the top electrode film 130a, the third insulating film 124a and the dielectric film 122a may be etched using the third photoresist pattern 193 as a mask. A top electrode 130, an insulating member 124 and a dielectric film pattern 122 are thereby formed and the bottom electrode 120 is exposed. The third photoresist pattern 193 may then be removed. After etching the insulating film 124a, the insulating member 124 may be formed along the edges (e.g., the periphery of the top surface) of the dielectric film pattern 122 and thus the insulating member 124 may have a ring shape connected around the edges over the dielectric film pattern 122. The top surface of the insulating member 124 decreases in height from the edges towards the central portion of the dielectric film pattern 122. That is, in cross-sectional views of the insulating member 124 and dielectric film pattern 122, the top surface of the insulating member 124 is rounded in a “U” shape. Therefore, the top electrode 130 formed over the dielectric film pattern 122 and insulating member 124 is rounded up in the portions where the top electrode 130 approaches the edge of the dielectric film pattern 122. The top electrode 130 and bottom electrode 120 may be spaced in the central part of the electrode by the thickness of the dielectric film pattern 122. The top electrode 130 and bottom electrode 120 may be spaced at the edge portion of the electrode by the thickness of the dielectric film pattern 122 and insulating member 124. In other words, the edge of the top electrode 130 is more distant from the bottom electrode 120 than the central portion of the top electrode 130, such that a parasitic capacitance between the two electrodes is reduced.

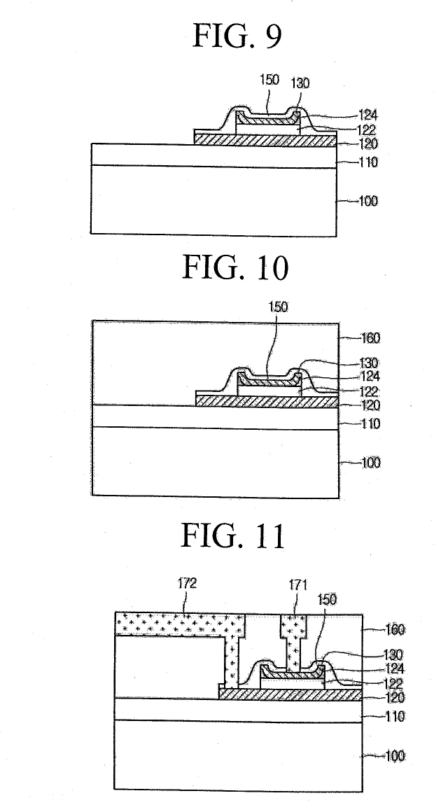

As shown in example FIG. 9, a first insulating film 150 which covers the bottom electrode 120 and top electrode 130 may be formed. Thereafter, as shown in example FIG. 10, a second insulating film 160 may be formed over the substrate 100 over which the first insulating film 150 is formed. The first insulating film 150 and second insulating film 160 may include at least one of an oxide film and a nitride film.

As shown in example FIG. 11, the second insulating film 160 and first insulating film 150 are selectively etched to form vias which expose a portion of the top electrode 130 and a portion of the bottom electrode 120. Metal is deposited in the vias, thereby forming a first wire 71 contacting the top electrode 130 and a second wire 172 contacting the bottom electrode 120.

With a capacitor for a semiconductor device and a method for fabricating the same according to embodiments, capacitor properties are improved and capacitor values are maintained as constant by reducing a parasitic capacitance generated from edges of a capacitor electrode. Therefore, embodiments make it possible to improve semiconductor device properties and yields.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An apparatus comprising:
a bottom electrode formed over a semiconductor substrate;
a dielectric film pattern formed over the bottom electrode;
an insulating member formed over a peripheral portion of a top surface of the dielectric film pattern; and
a top electrode formed over the insulating member and dielectric film pattern.

2. The apparatus of claim 1, further comprising:
a first insulating film covering the bottom electrode and top electrode;
a first wire passing through the first insulating film and connected to the top electrode; and
a second wire passing through the first insulating film and connected to the bottom electrode.

3. The apparatus of claim 2, further comprising:
a second insulating film covering the bottom electrode and the top electrode,
wherein the first insulating film is formed flat over the top portion of the second insulating film.

4. The apparatus of claim 3, wherein the second insulating film includes a silicon nitride film.

5. The apparatus of claim 1, wherein the insulating member is made of an oxide film.

6. The apparatus of claim 1, wherein the insulating member is made of a low dielectric constant dielectric material.

7. The apparatus of claim 1, further comprising a pad nitride layer formed over the semiconductor substrate, the pad nitride layer formed below the bottom electrode.

8. The apparatus of claim 1, wherein a top surface of the insulating member has a greater height over an outer peripheral portion of the top surface of the dielectric film pattern, and a reduced height over an inner peripheral portion of the top surface of the dielectric film pattern.

9. The apparatus of claim 1, wherein the distance between the top electrode and bottom electrode becomes greater at the edges of the top and bottom electrodes than the distance between the top electrode and bottom electrode at a central portion of the top and bottom electrodes.

10. The apparatus of claim 1, wherein the top electrode and the bottom electrode are electrically insulated from each other by the dielectric film pattern, such that the top electrode, bottom electrode, dielectric film pattern, and insulating member form a capacitor.

11. The apparatus of claim 1, wherein the insulating member forms a ring over the peripheral portion of the top surface of the dielectric film pattern.

12. A method comprising:
providing a semiconductor substrate;
forming a bottom electrode over the semiconductor substrate;
forming a dielectric film over the bottom electrode;
forming an insulating film over the dielectric film;
wet etching a portion of the insulating film to expose a portion of the dielectric film over a top portion of the bottom electrode;
forming a top electrode film over the exposed dielectric film and the insulating film; and
patterning the top electrode film, the insulating film and the dielectric film to form a top electrode, an insulating member disposed below the edge of the top electrode and a dielectric film pattern, respectively.

13. The method of claim 12, wherein forming an insulating film comprises forming an oxide film.

14. The method of claim 12, wherein the performing the wet etching on the portion of the insulating film comprises:
forming a photoresist pattern exposing a portion of the insulating film over a top portion of the insulating film; and
etching the insulating film using the photoresist pattern as a mask,
wherein the insulating film has a higher etch rate in a top region of the insulating film than that in a bottom region of the insulating film, such that the side of the insulating pattern is etched to be round.

15. The method of claim 12, further comprising:
after the forming the top electrode, forming a first insulating film covering the top electrode and bottom electrode;
forming a second insulating film over the substrate including the first insulating film; and
forming a first wire and a second wire each passing through the second insulating film and first insulating film, the first wire connected to the top electrode and the second wire connected to the bottom electrode.

16. The method of claim 12, wherein the dielectric film pattern is disposed in a central part between the top electrode and bottom electrode, the dielectric film pattern and insulating film pattern are disposed in an edge part between the top electrode and the bottom electrode, and the distance between the top electrode and bottom electrode becomes greater at the edge part than at the central part.

17. The method of claim 12, wherein the wet etching a portion of the insulating film is performed such that, after patterning the insulating film to form an insulating member, a top surface of the insulating member has a greater height over an outer peripheral portion of the top surface of the dielectric film pattern, and a reduced height over an inner peripheral portion of the top surface of the dielectric film pattern.

18. The method of claim 12, wherein the top electrode and the bottom electrode are formed to be electrically insulated from each other by the dielectric film pattern, such that the top electrode, bottom electrode, dielectric film pattern, and insulating member form a capacitor.

19. The method of claim 12, wherein patterning the insulating film forms a ring over a peripheral portion of the top surface of the dielectric film pattern.

20. The method of claim 12, further comprising forming a pad nitride layer over the semiconductor substrate and below the bottom electrode.
